(19) United States
(12) Patent Application Publication
(10) Pub. No.: US 2008/0088325 A1
(43) Pub. Date: Apr. 17, 2008

(54) Method and system for performing embedded diagnostic application at subassembly and component level

(76) Inventors: David W. Murray, Windsor, CA (US); Kim Chung Thi Thanh, Rohnert Park, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/515,060

(22) Filed: Sep. 1, 2006

(51) Int. Cl. G01R 31/02

(52) U.S. Cl. 324/754

(57) ABSTRACT

A method for performing a diagnostic test on a piece of equipment comprises performing a component level diagnostic test on the piece of equipment, the component level diagnostic test employing a component-level model of the piece of equipment; using the results of the component-level diagnostic test to determine whether a faulty component of the piece of equipment can be identified; and, if the component-level diagnostic test identifies a faulty component, then performing a sub-component level diagnostic test on the identified faulty sub-component, the sub-component level diagnostic test employing a sub-component level model of the identified failed component.

### BACKGROUND OF THE INVENTION

The present invention relates to diagnostic testing for electronic equipment.

Conventional diagnostic testing arrangements have involved coupling a test system, such as a production line Unix workstation, to an instrument or piece of equipment to be tested. Troubleshooting software applications, in the form of BASIC or C language programs or shell scripts, etc., reside within the test system.

When such troubleshooting software applications are executed, the test system, and the instrument to be tested, communicate through a communication interface. For instance, many such troubleshooting applications use an IEEE 488 General Purpose Interface Bus (GPIB) connection between the UNIX workstation and the instrument.

It would be advantageous to employ standard network communications for such diagnostic testing, obviating the need for a diagnostic-specific interface such as the GPIB and allowing for remote testing. It would also be advantageous to execute diagnostic testing on-board the equipment to be tested.

### SUMMARY OF THE INVENTION

A method for performing a diagnostic test on a piece of equipment comprises performing a component level diagnostic test on the piece of equipment, the component level diagnostic test employing a component-level model of the piece of equipment; using the results of the component-level diagnostic test to determine whether a faulty component of the piece of equipment can be identified; and, if the component-level diagnostic test identifies a faulty component, then performing a sub-component level diagnostic test on the identified faulty sub-component, the sub-component level diagnostic test employing a sub-component level model of the identified failed component.

Further features and advantages of the present invention, as well as the structure and operation of preferred embodiments of the present invention, are described in detail below with reference to the accompanying exemplary drawings.

### BRIEF DESCRIPTION OF THE DRAWINGS

FIG. 1 is a block diagram showing an embodiment of the invention.

FIG. 2 is block diagram showing another embodiment of the invention.

FIG. 3 is a flowchart showing operation of an embodiment of the invention.

FIG. 4 is a detailed block diagram showing an embodiment of the invention.

### DETAILED DESCRIPTION

A system embodying the invention includes self-contained embedded diagnostics for a piece of electronic equipment. Among other fields, such a system may be employed in a measurement apparatus for radiofrequency (hereinafter “RF”) systems.

In such systems, it is desirable to be able to self-diagnose problems which can be solved by replacing sub-assemblies, cables, etc., without requiring the use of external test and measurement equipment. When such a problem is diagnosed, service personnel not necessarily requiring great expertise or training, can replace the problem component.

In the discussion which follows, the term “indicted” will be used to describe a component, sub-assembly, etc., for which a problem has been diagnosed. Also, the terms “component” and “communication component” will be used interchangeably, to refer broadly and without limitation to any cable, interface, component, circuit board, module, etc., within a communications system, for which a fault may occur. The term “fault” will refer to any problem that is, or can be, isolated within a particular component of the communication system. In particular, a “sub-assembly” of a piece of equipment is a functional module which is designed to be easily removed and replaced, as needed. In general, a piece of equipment is made up of a plurality of sub-assemblies, and a sub-assembly is made up of a plurality of parts. For purposes of the discussion that follows, the terms “component” and “sub-component” will be used, to make clear the hierarchy of one component comprising multiple sub-components. However, in some embodiments of the invention, the “components” will be sub-assemblies as defined above, and the “sub-components” will be parts of one of such sub-assemblies.

A diagnostic test performed by a system embodying the invention can identify an indicted component, a failing component, or the component most likely to fail or to have failed. Also, the particular nature of the fault or failure can be identified.

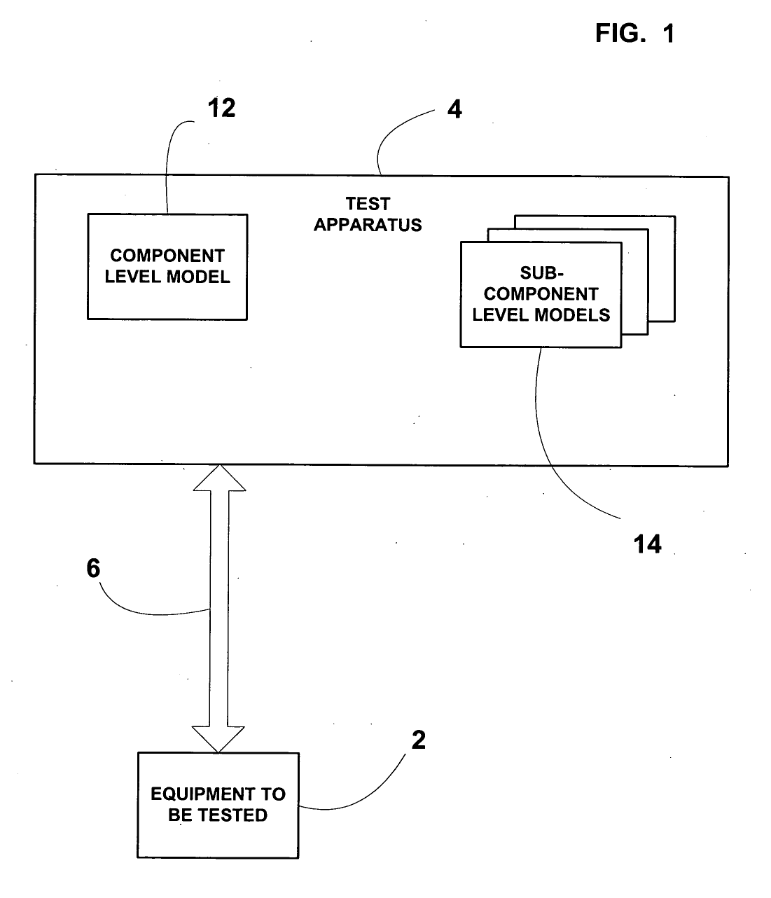

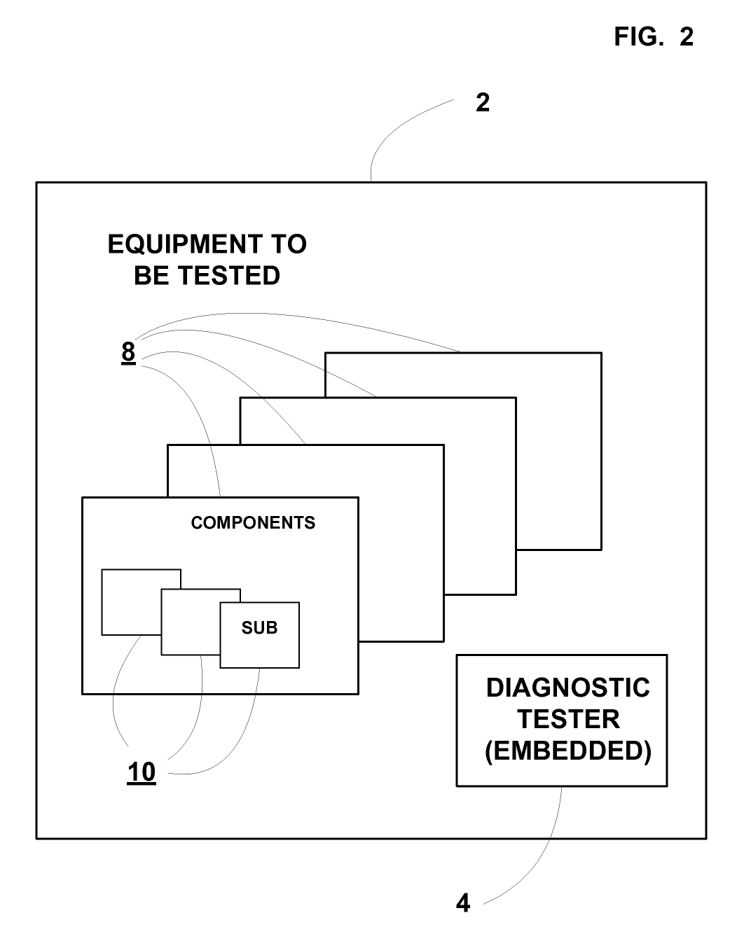

FIGS. 1 and 2 are schematic block-level diagrams of an apparatus according to embodiments of the invention. The apparatus of the invention may be embodied within multiple distinct modules of a communication system (FIG. 1), or may be embedded within a piece of communication equipment to be tested (FIG. 2). Some of the elements shown are common to the embodiments, as will be discussed below.

In FIG. 1, a piece of equipment 2 is to be tested. A test apparatus 4 communicates with the equipment 2 over a communication link 6, to direct the testing as will be described. The test apparatus 4 includes models of the equipment 2, that are used in the diagnostic testing.

In FIG. 2, the equipment 2 is shown in more detail, as containing a variety of components, shown collectively and schematically as 8. The components 8 are made up of sub-components which, in the example of one of the components 8, are shown collectively and schematically as 10. The components 8, and their respective subcomponents 10, have various structures and functions suitable for the particular nature of the equipment 2. It will be understood that the foregoing is also true for the equipment 2 shown in FIG. 1, although not all of the components 8, etc., are shown in FIG. 1.

Referring again to FIG. 1, the test apparatus 4 includes a component-level model 12 of the equipment 2. The component-level model 12 is employed in performing a component-level diagnostic test on the equipment 2, as will be described below. The test apparatus 4 also includes sub-component-level models 14 of the respective components 8 of the equipment 2. When a faulty component 8 is detected during a diagnostic test, the test apparatus 4 can then run a sub-component-level diagnostic test on the faulty component 8, employing the sub-component-level model 14 for the faulty component.

It will be understood that the foregoing discussion of the test apparatus 4 of FIG. 1 is also true for the test apparatus 4 shown in FIG. 2, although not all of the models 12 and 14 are shown in FIG. 2. The main distinction between the embodiments of FIGS. 1 and 2 is whether the test apparatus 4 is embedded within the equipment 2, or is a separate device. Embodiments of the invention may implement the test apparatus 4 either embedded or separately.

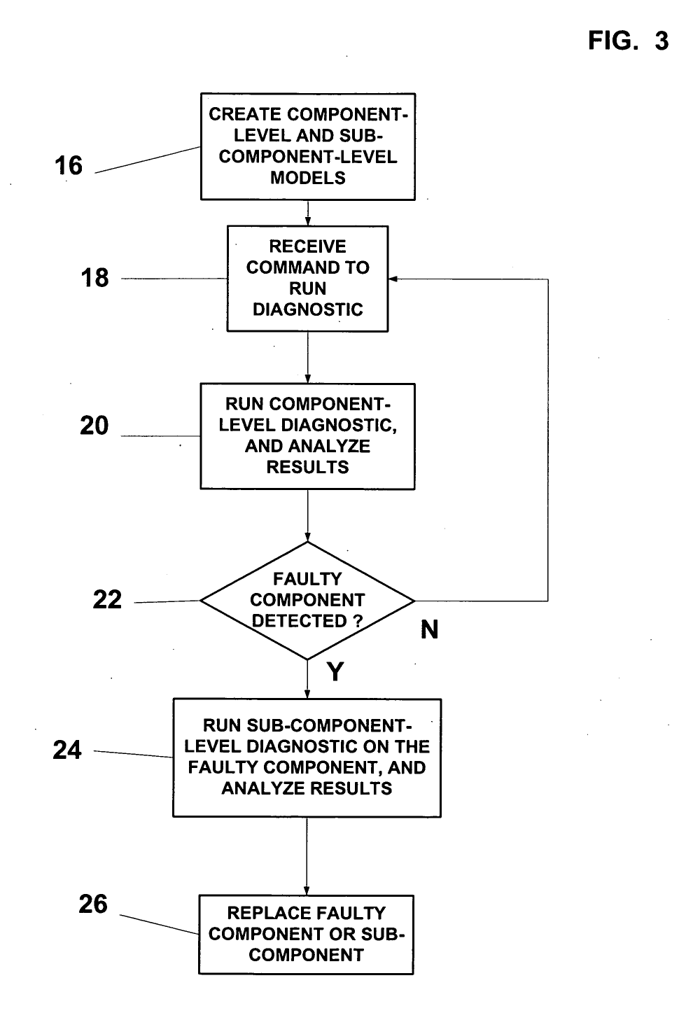

FIG. 3 is a flowchart showing operation of an embodiment of the invention. Initially, diagnostic capability is implemented for a given piece of equipment 2. Such implementation includes creating (16) the component-level model 12 and the sub-component-level models 14. The models 14 and 16 are distributed for use by the equipment 2 and its operators in a suitable manner. For instance, where the test apparatus is embedded in the equipment 2 as shown in FIG. 2, the models 14 and 16 may be installed in the equipment 2 as part of an initial configuration prior to shipping the equipment 2 to the customer. Alternatively, the models 14 and 16 may be installed on a remote test apparatus 4 as shown in FIG. 1.

In operation, a command to run a diagnostic test is received (18). The command may be entered by an operator through a user interface on either the remote test apparatus of FIG. 1 or the equipment 2 of FIG. 2 containing the embedded test apparatus 4. Alternatively, the diagnostic test run command may be generated automatically, either as a scheduled or time-triggered event, or in response to a detected condition such as an operational failure of the equipment 2.

The component-level diagnostic test is then run (20). The diagnostic test will produce results, which may then be analyzed. In particular, it is determined from the results whether (22) there is a fault in the equipment 2. If no fault is detected, then the embodiment performs other operations, including waiting to receive (18) further commends to run diagnostic tests.

If so, it is determined which components 8 is indicted as being faulty, or is indicted as appearing to be the most likely to be faulty. If more than one component 8 could be faulty, the analysis may also include estimation and ranking of the likelihood that each indicted component could contain the fault.

Then, a further level of test is performed based on the results of the analysis. For the component 8 believed to be faulty, a sub-component-level diagnostic test is run (24). The results of the sub-component-level diagnostic test may enable the operator to further isolate the fault down to a faulty sub-component 10 within the faulty component 8.

The results of the component-level and/or sub-component-level diagnostic tests are reported to the operator, who can then replace (26) the indicted component or sub-component, and restore the equipment 2 to proper operation.

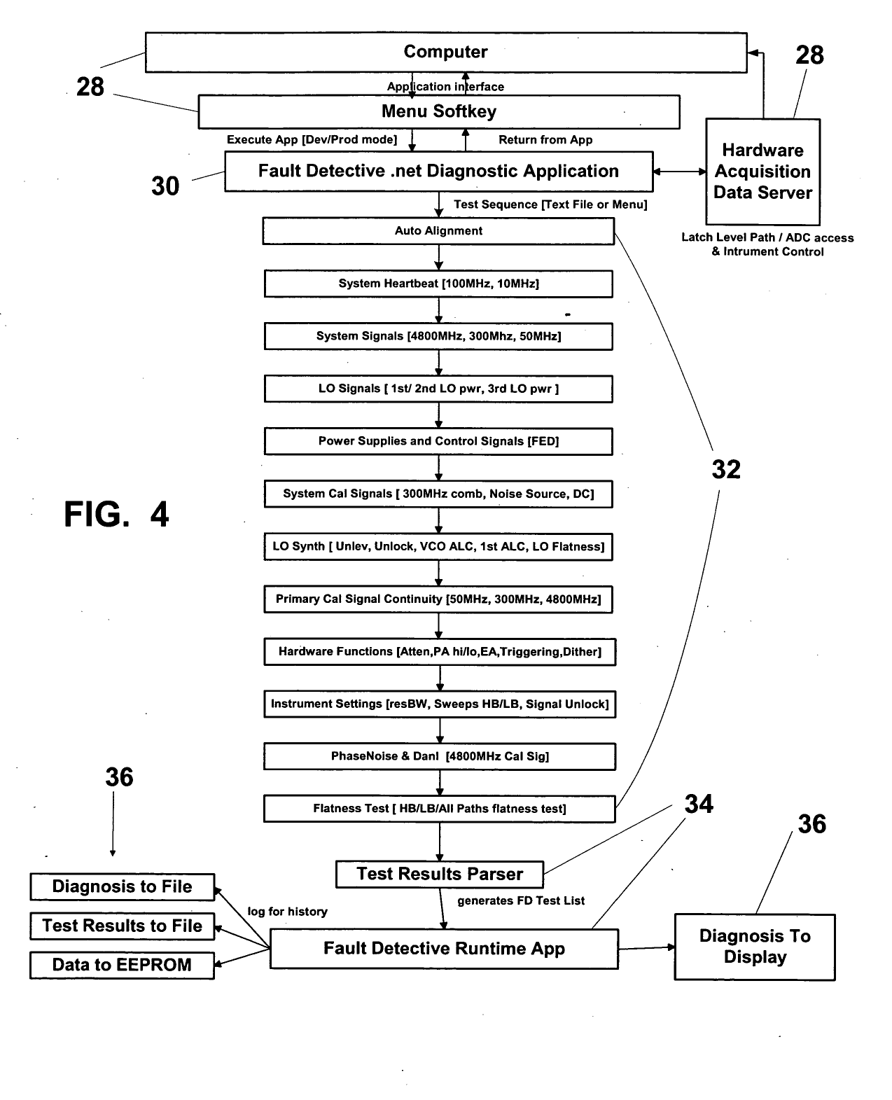

FIG. 4 is a detailed block diagram of one exemplary specific embodiment of the test apparatus 4. As a whole, what is shown is a fully self-contained embedded diagnostic designed for a spectrum analyzer. The various elements of FIG. 4 are believed to be self-explanatory as labeled, so the discussion here will focus on a high-level explanation of the elements by group.

Computer processing and firmware functionality are shown as elements labeled 28. These include a computer processor (which may be a general purpose processor performing other functions related to operation of the equipment 2, a user interface such as a menu softkey, from which functions such as diagnostic tests can be selected, and a hardware acquisition data server (HADS), which is a software interface for hardware control used in equipment such as measurement products.

A diagnostic test application 30, here designated by the name “FaultDetective.net”, includes tests, logic, and application calls, for creating models of hardware which diagnoses hardware failures in equipment to be tested.

The embedded diagnostic system of FIG. 4 leverages both the FaultDetective.net application and the HADS as part of its design for embodiments the embedded diagnostic test system.

A menu list of tests, generally shown as 32, run as appropriate for either component-level testing of the spectrum analyzer as a whole, or for sub-component-level testing of discrete spectrum analyzer components, as would be understood by a person skilled in the spectrum analyzer arts, and particularly such a person who has knowledge of the calibration of spectrum analyzers.

For monitoring the tests, and receiving and analyzing the results, additional applications are shown, including a test results parser for receiving and parsing the results for analysis, and a run-time portion of the FaultDetective application.

Output applications, tasks, elements, etc, are shown as 36. These include elements for generating test results and a fault diagnosis, including identifying a faulty component or sub-component and the nature of the fault, for filing. Also included is a tool for storing the results in a test results store, which might for instance include an EEPROM on-board the component or sub-component. Additionally, a display, printer, or other output interface device may be provided, to communicate the test results and diagnosis to the operator.

Although the present invention has been described in detail with reference to particular embodiments, persons possessing ordinary skill in the art to which this invention pertains will appreciate that various modifications and enhancements may be made without departing from the spirit and scope of the claims that follow.

1. An embedded diagnostic apparatus for performing diagnostic tests on a piece of equipment, the piece of equipment including a plurality of components, the apparatus embedded within the piece of equipment and comprising:
a component level model of the piece of equipment;
a component-level diagnostic agent that utilizes the component level model for running a diagnostic against the piece of equipment to identify a faulty component;
a sub-component-level model of the identified faulty component; and
a sub-component-level diagnostic agent for running a diagnostic against the identified faulty component.

2. An apparatus as recited in claim 1, wherein the component-level diagnostic agent includes a test library of functions for the piece of equipment

3. An apparatus as recited in claim 2, further comprising an environment file for controlling test variables of the test library of functions.

4. An apparatus as recited in claim 1, wherein:
the components each include a fault report store; and
the apparatus further comprises a reporter for entering a fault report into the fault report store of the identified faulty component.

5. An apparatus as recited in claim 4, wherein the fault report stores each include an electrically erasable programmable read-only memory (EEPROM).

6. A method for performing a diagnostic test on a piece of equipment which includes an embedded diagnostic apparatus, the method comprising:
the embedded diagnostic apparatus performing a component level diagnostic test on the piece of equipment, the component level diagnostic test employing a component-level model of the piece of equipment;
the embedded diagnostic apparatus using the results of the component-level diagnostic test to determine whether a faulty component of the piece of equipment can be identified;
if the component-level diagnostic test identifies a faulty component, then the embedded diagnostic apparats performing a sub-component level diagnostic test on the identified faulty sub-component, the sub-component level diagnostic test employing a sub-component level model of the identified failed component.

7. A method as recited in claim 6, further comprising:
replacing a faulty component that was identified using the results of the component-level diagnostic test; and
the embedded diagnostic apparatus performing an equipment-level diagnostic test on the piece of equipment after the faulty component is replaced.

8. A method as recited in claim 6, wherein:
the embedded diagnostic apparatus includes failure report stores residing on respective components of the piece of equipment; and
the method further comprises:
the embedded diagnostic apparatus entering a failure report describing the faulty component into a failure report store of the identified faulty component; and
analyzing the faulty component separately from the piece of equipment.

9. A method as recited in claim 6, further comprising:
the embedded diagnostic apparatus generating a component-level model of the piece of equipment; and
the embedded diagnostic apparatus employing the component-level model in the performing a component-level diagnostic test.

10. A method as recited in claim 9, further comprising:
the embedded diagnostic apparatus generating sub-component-level models of the sub-components of the respective components; and
the embedded diagnostic apparatus employing the component-level model in the performing a component-level diagnostic test.
